(19) United States
(12) Patent Application Publication
(10) Pub. No.: US 2008/0105935 A1
(43) Pub. Date: May 8, 2008

(54) Micromachine Device

(76) Inventors: Hiroshi Ogura, Tokyo (JP); Seiji Ueda, Shiga (JP); Katsuhiro Makihata, Kanagawa (JP)

Correspondence Address: MCDERMOTT WILL & EMERY LLP, 600 13TH STREET, NW, WASHINGTON, DC, 20005-3096, US

(21) Appl. No.: 11/661,355

(22) PCT Filed: Aug. 15, 2005
(86) PCT No.: PCT/JP05/14901

§ 371 Date: Feb. 28, 2007

(30) Foreign Application Priority Data
Aug. 31, 2004 (JP) 2004-251571

(51) Int. Cl. H01L 29/84

(52) U.S. Cl. 257/415; 257/E29.324

(57) ABSTRACT

A micromachine device includes a pad 107a and a pad 107b formed of a polysilicon doped with impurities.

### TECHNICAL FIELD

The present invention relates to a device produced using thin film processing and specifically to a micromachine device called a micromachine or MEMS (Micro Electro Mechanical Systems).

### BACKGROUND ART

A widely-employed conventional wiring method for electric connection between a device, such as a semiconductor element, or the like, and a substrate has been wire bonding with a wire made of Au (gold), Al (aluminum), or the like. In general, a connection pad of a device, such as a semiconductor element, or the like, is formed of an Al film, and a wire made of Au or Al is bonded to the Al film of the pad by a wire bonding method using ball bonding or wedge bonding. This is because the pad and wirings of the semiconductor element are formed of an Al film.

In recent years, on the other hand, to decrease the size of a device produced by conventional machining, a method called a micromachining technique, which has been developed from a production method of semiconductor elements, has been used to produce a micromachine device. In the micromachine device, an Al film or a polysilicon film doped with impurities is generally used as the wiring material (conduction material). The micromachine device does not discharge its function until it is electrically connected to other substrates or devices. To this end, the micromachine device is provided with an electrode for electrical connection, and the electrode is electrically connected to other substrates or devices by wire bonding. In the case where the wiring material of the micromachine device is an Al film, a special structural consideration is not necessary in the electrode structure for desirable connection of the Al film with a Au wire or Al wire which is the wire bonding wiring material. On the other hand, in the case where the wiring material of the micromachine device is a polysilicon film doped with impurities, the electrode structure shown in FIG. 4 is generally used (see Patent Document 1).

As shown in FIG. 4, an insulation film 2 is provided on a silicon substrate 1, and a wiring 3 formed of a polysilicon film doped with impurities is provided on the insulation film 2. An insulation film 4 is provided to cover the wiring 3. The insulation film 4 has an opening through which the wiring 3 is partially exposed. A pad 5 of Au is provided in the opening to be connected to the wiring 3. A wire 6 made of Au or Al is connected to the pad 5.

Patent Document 1: Japanese Laid-Open Patent Publication No. 63-318756

### DISCLOSURE OF INVENTION

### Problems to be Solved by the Invention

However, in the case where the polysilicon film doped with impurities is used as the wiring material for the micromachine device, the above-described wiring method entails the following problems.

The electrode structure shown in FIG. 4 requires the process of forming a Au film or a metal composite film including a Au film in the uppermost layer as the pad 5. Accordingly, the number of process steps increases, and the production cost also increases. Further, in the electrode structure shown in FIG. 4, the wiring 3 (polysilicon film) and the pad 5 (Au film or metal composite film), which face each other with the insulation film 4 interposed therebetween, constitute a capacitor, and as a result, parasitic capacitance occurs. This parasitic capacitance deteriorates the characteristics of the device. Namely, this parasitic capacitance inhibits the functions of the micromachine device.

In view of the above circumstances, an objective of the present invention is to realize an electrode structure of a micromachine device which enables reduction of the parasitic capacitance without increasing the number of process steps.

### Means for Solving the Problems

To achieve the above objective, the first micromachine device according to the present invention includes a bonding pad formed of a polysilicon doped with impurities.

According to the first micromachine device of the present invention, a wiring material of a polysilicon doped with impurities is used as a material for the bonding pad. Thus, as compared with an instance where a bonding pad is newly formed using a metal material different from the wiring material, such a step can be omitted. Therefore, the production cost can be reduced. Furthermore, since metal is not used as the bonding pad material, a structure where a bonding pad and a wiring or electrode face each other with an insulation film interposed therebetween can be avoided. Thus, the parasitic capacitance can be greatly reduced.

The second micromachine device according to the present invention is a micromachine device including: a capacitor formed by a first electrode and a second electrode; a bonding pad provided on the first electrode; and a protective insulation film provided over the first electrode and having an opening above the bonding pad, wherein both the first electrode and the bonding pad are formed of a polysilicon doped with impurities.

According to the second micromachine device of the present invention, a wiring material of a polysilicon doped with impurities is used as a material for the bonding pad. Thus, as compared with an instance where a bonding pad is newly formed using a metal material different from the wiring material, such a step can be omitted. Therefore, the production cost can be reduced. Furthermore, since metal is not used as the bonding pad material, a structure where a bonding pad and a wiring or electrode face each other with an insulation film interposed therebetween can be avoided. Thus, the parasitic capacitance can be greatly reduced.

In the first or second micromachine device of the present invention, it is preferable that a wire made of aluminum is directly bonded onto the bonding pad by an eutectic reaction.

With such a structure, the wire made of aluminum and the bonding pad, i.e., the polysilicon doped with impurities, can be more firmly bonded, so that the reliability of the device can be improved.

### Effects of the Invention

According to the present invention, the increase in the number of process steps, i.e., the increase in production cost, can be suppressed. Further, by directly bonding a wire to a bonding pad which is part of a wiring formed of a polysilicon doped with impurities, the parasitic capacitance in the vicinity of the bonding pad can be suppressed. Thus, the reliability of the device is improved.

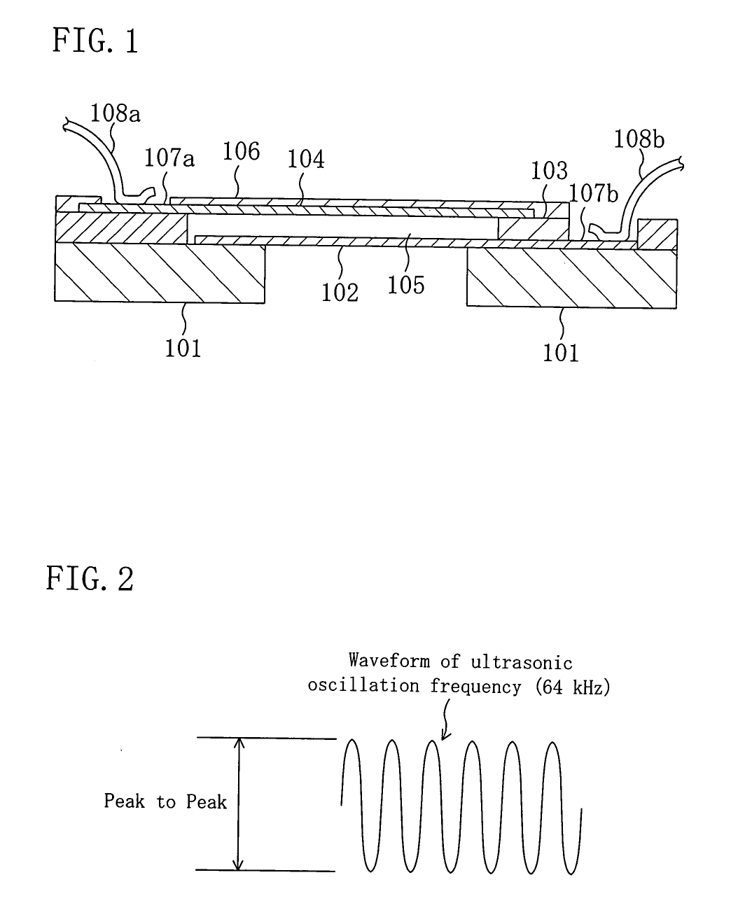

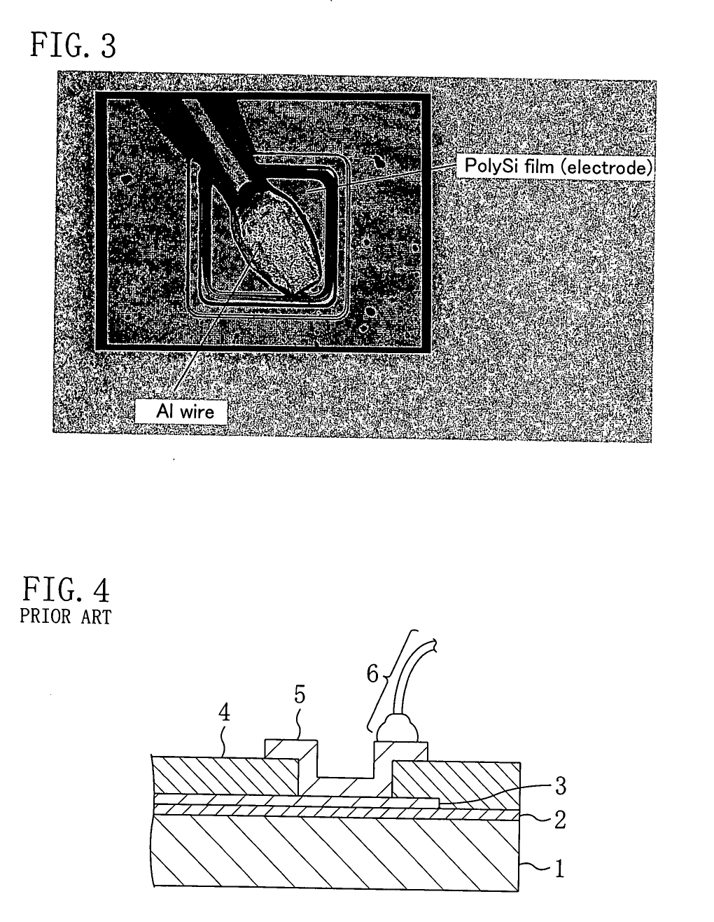

### BRIEF DESCRIPTION OF DRAWINGS

[FIG. 1] FIG. 1 is a cross-sectional view of a micromachine device according to an embodiment of the present invention.

[FIG. 2] FIG. 2 illustrates the definition of the bonding power which is a bonding condition for the micromachine device according to an embodiment of the present invention.

[FIG. 3] FIG. 3 is a magnified photograph illustrating a pad section in the micromachine device according to an embodiment of the present invention.

[FIG. 4] FIG. 4 is a cross-sectional view illustrating a pad section in a conventional micromachine device.

### DESCRIPTION OF REFERENCE NUMERALS

101 Silicon substrate
102 Lower electrode
103 Interlayer insulation film
104 Upper electrode
105 Space
106 Protection film
107a Pad
107b Pad
108a Wire
108b Wire

### BEST MODE FOR CARRYING OUT THE INVENTION

Hereinafter, a micromachine device according to an embodiment of the present invention is described with reference to the drawings.

FIG. 1 is a cross-sectional view illustrating the concept of the micromachine device according to an embodiment of the present invention and shows the basic structure of the micromachine device. As shown in FIG. 1, a lower electrode 102 is provided on a silicon substrate 101. It should be noted that the back surface of the lower electrode 102 is partially exposed by removing part of the silicon substrate 101. An upper electrode 104 is provided in a region extending above the silicon substrate 101, which includes a region extending above the lower electrode 102, with an interlayer insulation film 103 interposed between the silicon substrate 101 and the upper electrode 104. At least part of the interlayer insulation film 103 superposed above the removed portion of the silicon substrate 101 is also removed, whereby a space 105 is formed between the lower electrode 102 and the upper electrode 104. Herein, the lower electrode 102 and the upper electrode 104 are formed of a polysilicon doped with impurities. Further, a protection film 106 is provided over the upper electrode 104. The protection film 106 has an opening through which an end of the upper electrode 104 is exposed, such that the exposed end of the upper electrode 104 serves as a pad 107a. The protection film 106 and the interlayer insulation film 103 have an opening through which an end of the lower electrode 102 is exposed, such that the exposed end of the lower electrode 102 serves as a pad 107b. On the pad 107a and the pad 107b, wires 108a and 108b made of aluminum are respectively bonded using a eutectic reaction by wedge bonding.

The basic structure of the micromachine device of this embodiment is a structure having two parallel planar electrodes as shown in FIG. 1, i.e., the lower electrode 102 and the upper electrode 104. With such a structure that the space (air gap) 105 exists between the upper electrode 104 and the lower electrode 102, the micromachine device of this embodiment functions as a pressure sensor for detecting the change in pressure around the device.

For example, when pressure, such as air pressure, or the like, is applied to the lower electrode 102, the pressure bends the lower electrode 102 so that the distance between the lower electrode 102 and the upper electrode 104 (i.e., the thickness of the space 105) varies. Since the lower electrode 102 and the upper electrode 104 constitute a parallel plate capacitor with air as a dielectric (i.e., the space 105 serving as a dielectric layer), the change in distance between the lower electrode 102 and the upper electrode 104 results in a change in capacitance of the capacitor. By detecting and outputting this change in capacitance, the change in pressure can be obtained as an output value.

The lower electrode 102 and the upper electrode 104 are formed of an electrically-conductive material. In many micromachine devices, the lower electrode 102 and the upper electrode 104 are formed of a polysilicon film containing impurities diffused therein. This is because the membrane stress of the polysilicon film can be adjusted by adjusting the film formation conditions, annealing conditions, etc. Herein, for example, in the device structure shown in FIG. 1, the stress of the polysilicon film of the lower electrode 102 to which the pressure is applied is a significant factor. Specifically, the tension of the polysilicon film which forms the lower electrode 102 is proportional to the product of the stress of the polysilicon film and the thickness of the polysilicon film. The tension of the polysilicon film affects the sensitivity for detecting the change in pressure. Thus, the sensitivity of the pressure sensor can be determined by adjusting the stress of the polysilicon film. For example, a sensor for detecting slight pressure can be realized by decreasing the tension of the polysilicon film. Conversely, a sensor for detecting large pressure can be realized by increasing the tension of the polysilicon film.

Next, the method for bonding the wires 108a and 108b respectively to the pads 107a and 107b shown in FIG. 1 is described.

The principal parameters of the bonding conditions of a wedge bonder used in this embodiment include the oscillation frequency of an ultrasonic wave, bonding load, bonding time, and bonding power. Hereinafter, the result of an experiment conducted by the present inventors as to connection of an aluminum wire to a polysilicon film doped with impurities is described.

The apparatus used in the experiment was a Model 7400D wedge bonder manufactured by West Bond, Inc. The wedge used was CKNOE-1/16-750-52-F2525-MP, which is a 45°-type wedge manufactured by DEWELY. The Al wire used was a wire of an Al—Si alloy (silicon content: 1 at %) having a diameter (φ) of 30 μm. The oscillation frequency was 64 kHz. The bonding load was from 1 to 60 gf (from 9.8×1 to 9.8×60 mN). The bonding power was from 1 to 13 V. The bonding time was from 1 to 100 msec. Namely, the experiment was carried out with the varying values set for the bonding load, bonding time, and bonding power. The bonding temperature was the room temperature.

The definition of the bonding power is now described with reference to FIG. 2. The waveform shown in FIG. 2 is the waveform of ultrasonic oscillation frequency at 64 kHz. The voltage value (V) of the “Peak to Peak” of the waveform is referred to as the bonding power in this experiment.

As for the bonding load, if it exceeds 60 gf, the device is sometimes damaged irrespective of the bondability of wire. In view of such, in this experiment, the bonding load was 60 gf or less. The bonding time was 0.1 second (100 msec) or less in consideration of the productivity. The bonding power set as an experiment condition was equal to or smaller than 13 V which was the maximum power of an ultrasonic oscillator.

In this experiment, bonding of the aluminum wire onto the polysilicon film doped with impurities was possible when the bonding load was from 25 to 60 gf, the bonding power was from 3.9 to 13 V, and the bonding time was from 42 to 100 msec.

In this experiment, the bondability of the polysilicon film and the aluminum wire was judged to be “bondable” when the bonding strength in a pull test experiment was 5 gf (9.8×5 mN) or greater.

The picture shown in FIG. 3 is a magnified photograph illustrating a bonding of a polysilicon film doped with impurities and an aluminum wire where the bonding load was 30 gf, the bonding time was 47 msec, and the bonding power was 2 V. Herein, the bonding illustrated in FIG. 3 was realized by an eutectic reaction of the polysilicon film doped with impurities and the aluminum wire. The bonding strength measured in the pull test experiment was 15 gf (9.8×15 mN).

Further, it was found from this experiment that the practical bonding conditions are desirably such that the bonding load is from 28 to 32 gf (from 9.8×28 to 9.8×32 mN), the bonding time is from 45 to 50 msec, and the bonding power is from 4.2 to 5.0 V.

As described hereinabove, according to this embodiment, the aluminum wires 108a and 108b can be bonded respectively to the pads 107a and 107b formed of a polysilicon doped with impurities. Further, the wiring material of a polysilicon doped with impurities is used as the material for the pads 107a and 107b, i.e., the bonding pads. Thus, as compared with an instance where a bonding pad is newly formed using a metal material different from the wiring material, such a step can be omitted. Therefore, the production cost can be reduced. Furthermore, since metal is not used as the bonding pad material, a structure where a bonding pad and a wiring or electrode face each other with an insulation film interposed therebetween can be avoided. Thus, the parasitic capacitance can be greatly reduced.

Thus, production of a micromachine device is possible with less production cost and without occurrence of parasitic capacitance in a pad section.

### INDUSTRIAL APPLICABILITY

The present invention relates to a micromachine device wherein a wire is directly bonded onto a wiring or electrode formed of a polysilicon doped with impurities so that the parasitic capacitance in the vicinity of a bonding pad is suppressed and high reliability is realized. Thus, the present invention is extremely useful.

1-3. (canceled)

4. A micromachine device, comprising:
a first conductive film having a first electrode section and a first pad section; and
a second conductive film having a second electrode section and a second pad section,
wherein the first electrode section and the second electrode section face each other with an air gap interposed therebetween, and
the first conductive film and the second conductive film are each formed of a polysilicon doped with impurities.

5. The micromachine device of claim 4 wherein, on each of the first pad section and the second pad section, a wire made of aluminum is directly bonded by an eutectic reaction.

6. The micromachine device of claim 4, wherein:
a protection film is formed over a surface of the first conductive film opposite to the second conductive film except for the first pad section; and
the second conductive film bends according to a change in air pressure.
